(19) United States
(12) Patent Application Publication
(10) Pub. No.: US 2024/0234178 A1
(43) Pub. Date: Jul. 11, 2024

(54) SUBSTRATE PROCESSING APPARATUS, METHOD OF MANUFACTURING SEMICONDUCTOR DEVICE, SUBSTRATE PROCESSING METHOD AND NON-TRANSITORY COMPUTER-READABLE RECORDING MEDIUM

(71) Applicant: Kokusai Electric Corporation, Tokyo (JP)

(72) Inventor: Daiki KIMOTO, Toyama-shi (JP)

(73) Assignee: Kokusai Electric Corporation, Tokyo (JP)

(21) Appl. No.: 18/612,218

(22) Filed: Mar. 21, 2024

Related U.S. Application Data
(63) Continuation of application No. PCT/JP21/34903, filed on Sep. 22, 2021.

(51) Int. Cl. H01L 21/67; C23C 16/458; C23C 16/48; H01L 21/02; H01L 21/324

(52) U.S. Cl. CPC H01L 21/67115; C23C 16/4583; C23C 16/482; H01L 21/0217; H01L 21/324

(57) ABSTRACT

There is provided a technique that includes: a process chamber in which a plurality of substrates are processed; and a transfer chamber communicating with a lower portion of the process chamber and configured to be capable of accommodating: a substrate retainer configured to support the plurality of substrates; a heating structure configured to heat the plurality of substrates; and at least one heat retaining structure provided between the substrate retainer and the heating structure.

### CROSS-REFERENCE TO RELATED PATENT APPLICATION

This application is a bypass continuation application of PCT International Application No. PCT/JP2021/034903, filed on Sep. 22, 2021, in the WIPO, the entire contents of which are hereby incorporated by reference.

### BACKGROUND

### 1. Field

The present disclosure relates to a substrate processing apparatus, a method of manufacturing a semiconductor device, a substrate processing method and a non-transitory computer-readable recording medium.

### 2. Related Art

In a heat treatment process for a substrate (also referred to as a “wafer”) in a manufacturing process of a semiconductor device, for example, a vertical type substrate processing apparatus may be used. In the vertical type substrate processing apparatus, a plurality of substrates are arranged into a substrate retainer of the vertical type substrate processing apparatus and supported in a vertical direction by the substrate retainer, and the substrate retainer is loaded into a process chamber of the vertical type substrate processing apparatus. Thereafter, a process gas is introduced into the process chamber while the process chamber is heated to perform a substrate processing such as a film-forming process on the plurality of substrates. For example, according to some related arts, the film-forming process is disclosed.

### SUMMARY

According to the present disclosure, there is provided a technique capable of improving a heating efficiency for a substrate.

According to an aspect of the present disclosure, there is provided a technique that includes: a process chamber in which a plurality of substrates are processed; and a transfer chamber communicating with a lower portion of the process chamber and configured to be capable of accommodating: a substrate retainer configured to support the plurality of substrates; a heating structure configured to heat the plurality of substrates;

and at least one heat retaining structure provided between the substrate retainer and the heating structure.

### BRIEF DESCRIPTION OF THE DRAWINGS

FIG. 1 is a diagram schematically illustrating a substrate processing system according to one or more embodiments of the present disclosure.

FIG. 2 is a diagram schematically illustrating a cross-section of a process chamber and a boat storage chamber in a substrate processing apparatus according to the embodiments of the present disclosure, representing a state in which a boat accommodating a substrate is loaded into the process chamber.

FIG. 3 is a diagram schematically illustrating a heating apparatus according to the embodiments of the present disclosure when viewed from above.

FIG. 4 is a diagram schematically illustrating a cross-section of the heating apparatus according to the embodiments of the present disclosure.

FIG. 5 is a block diagram schematically illustrating a configuration of a controller configured to operate (control) each component of the substrate processing apparatus according to the embodiments of the present disclosure.

FIG. 6 is a flow chart schematically illustrating a process flow of a manufacturing process of a semiconductor device according to the embodiments of the present disclosure.

FIG. 7A is a diagram schematically illustrating a cross-section of the process chamber and a transfer chamber in a state in which an atmosphere pre-adjusting step is performed or in a state in which the substrate mounted (placed) on the boat is processed in the process chamber of the substrate processing apparatus according to the embodiments of the present disclosure.

FIG. 7B is a diagram schematically illustrating the cross-section of the process chamber and the transfer chamber in a state in which the boat accommodating the substrate is being transferred (unloaded) from the process chamber of the substrate processing apparatus according to the embodiments of the present disclosure.

FIG. 7C is a diagram schematically illustrating the cross-section of the process chamber and the transfer chamber in a state in which the boat on which the substrate is mounted is transferred (loaded) into the transfer chamber of the substrate processing apparatus according to the embodiments of the present disclosure.

FIG. 7D is a diagram schematically illustrating the cross-section of the process chamber and the transfer chamber in a state in which the boat on which the substrate is mounted is being transferred into the process chamber of the substrate processing apparatus according to the embodiments of the present disclosure.

FIG. 7E is a diagram schematically illustrating the cross-section of the process chamber and the transfer chamber in a state in which the boat on which the substrate is mounted is transferred into the process chamber of the substrate processing apparatus according to the embodiments of the present disclosure.

FIG. 8 is a diagram schematically illustrating a heating apparatus according to another embodiment of the present disclosure when viewed from above.

FIG. 9A is a diagram schematically illustrating a first gas supplier according to the embodiments of the present disclosure.

FIG. 9B is a diagram schematically illustrating a second gas supplier according to the embodiments of the present disclosure.

### DETAILED DESCRIPTION

### Embodiments of Present Disclosure

Hereinafter, one or more embodiments (also simply referred to as “embodiments”) of the technique of the present disclosure will be described in detail mainly with reference to the drawings. For example, the drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Configuration of Substrate Processing Apparatus

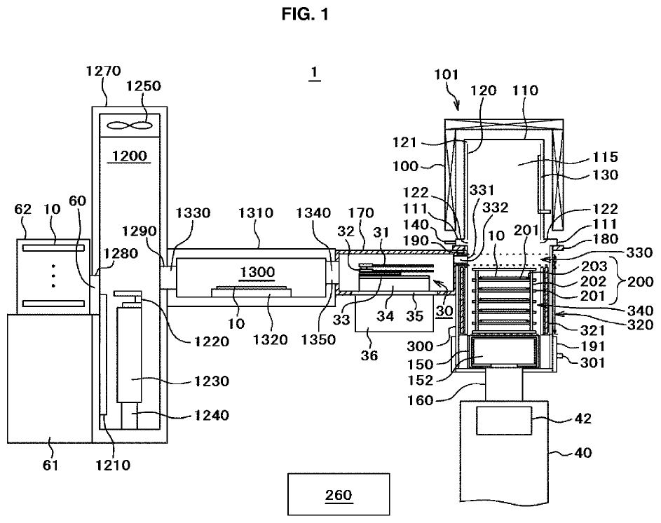

A semiconductor manufacturing apparatus according to the present embodiments is configured as a vertical type substrate processing apparatus (hereinafter, simply referred to as a “substrate processing system”) 1 capable of performing a substrate processing such as a heat treatment process. The substrate processing is performed as a part of a manufacturing process in a method of manufacturing a semiconductor device. The substrate processing system 1 according to the present embodiments is configured to process a plurality of substrates including a substrate 10. Hereinafter, the plurality of substrates including the substrate 10 mayalso be simply referred to as “substrates 10”. As shown in FIG. 1, the substrate processing system 1 is constituted mainly by an I/O stage (input/output stage) 61, an atmospheric transfer chamber 1200, a load lock chamber 1300, a vacuum transfer chamber 170 and a substrate processing apparatus 101.

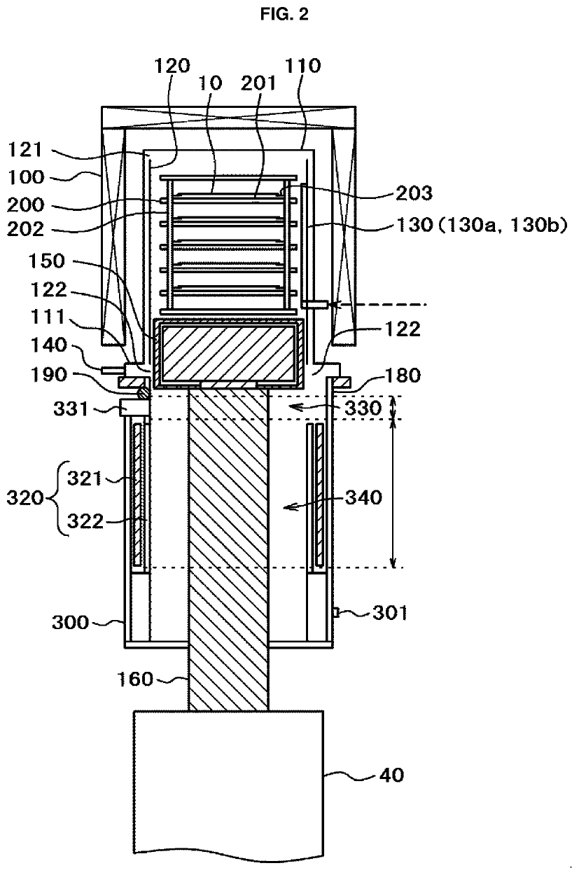

FIG. 1 is a diagram schematically illustrating a state in which a boat 200 supporting the substrates 10 is lowered into a transfer chamber 300 provided below a chamber 180 on a side of the vacuum transfer chamber 170, and FIG. 2 (which is a diagram schematically illustrating a part of FIG. 1) is a diagram schematically illustrating a state in which the boat 200 serving as a substrate retainer has been elevated into a first reaction tube 110. In the present specification, the vacuum transfer chamber 170 may also be referred to as a “transfer module”. In addition, the substrate processing apparatus 101 may also be referred to as a “process module”. Hereinafter, each configuration will be described in detail.

### Atmospheric Transfer Chamber 1200 and I/O Stage 61

The I/O stage (also referred to as a “loading port shelf”) 61 is provided at a front of the substrate processing system 1. The I/O stage 61 is configured such that a plurality of pods including a pod 62 serving as a container can be placed on the I/O stage 61. Hereinafter, the plurality of pods including the pod 62 mayalso be simply referred to as “pods 62”. The pod 62 is used as a carrier for transferring the substrate 10 such as a silicon (Si) substrate. The pod 62 is configured such that the substrates 10 can be accommodated in a multistage manner in a horizontal orientation in the pod 62. In addition, for example, a maximum of 25 substrates may be stored in the pod 62 as the substrates 10.

A cap 60 is installed at the pod 62. The cap 60 can be opened or closed by a pod opener 1210 described later. The pod opener 1210 is configured to open and close the cap 60 of the pod 62 placed on the I/O stage 61. When the pod opener 1210 opens a substrate loading/unloading port 1280 of the pod 62, the substrate 10 can be transferred (loaded) into or transferred (unloaded) out of the pod 62. The pod 62 is provided to or discharged from the I/O stage 61 by an in-process transfer device (not shown) such as a rail guided vehicle (RGV).

The I/O stage 61 is provided adjacent to the atmospheric transfer chamber 1200. The load lock chamber 1300, which will be described later, is connected to a side of the atmospheric transfer chamber 1200 other than a side at which the I/O stage 61 is provided.

An atmospheric transfer robot 1220, which serves as a first transfer robot configured to transfer the substrate 10, is provided in the atmospheric transfer chamber 1200. The atmospheric transfer robot 1220 is configured to be elevated or lowered by an elevator 1230 installed in the atmospheric transfer chamber 1200 and to be reciprocated laterally by a linear actuator 1240.

A clean air supplier (which is a clean air supply structure or a clean air supply system) 1250 capable of supplying clean air is installed at an upper portion of the atmospheric transfer chamber 1200.

The substrate loading/unloading port 1280 (through which the substrate 10 is loaded into or unloaded out of the atmospheric transfer chamber 1200) and the pod opener 1210 are provided at a front side of a housing 1270 of the atmospheric transfer chamber 1200. The I/O stage (that it, the loading port shelf) 61 is provided opposite to the pod opener 1210 with the substrate loading/unloading port 1280 interposed therebetween. That is, the I/O stage 61 is provided outside the housing 1270.

A substrate loading/unloading port 1290 (through which the substrate 10 is loaded into or unloaded out of the load lock chamber 1300) is provided at a rear side of the housing 1270 of the atmospheric transfer chamber 1200. The substrate loading/unloading port 1290 is opened or closed by a gate valve 1330 which will be described later. When the substrate loading/unloading port 1290 is opened by the gate valve 1330, the substrate 10 can be loaded into the load lock chamber 1300 or unloaded out of the load lock chamber 1300.

### Load Lock (L/L) Chamber 1300

The load lock chamber 1300 is provided adjacent to the atmospheric transfer chamber 1200. The vacuum transfer chamber 170, which will be described later, is provided at a side of a housing 1310 constituting the load lock chamber 1300 other than a side of the housing 1310 that is adjacent to the atmospheric transfer chamber 1200. Since an inner pressure of the housing 1310 is adjusted according to an inner pressure of the atmospheric transfer chamber 1200 or an inner pressure of the vacuum transfer chamber 170, the load lock chamber 1300 is constructed to withstand a negative pressure.

A substrate loading/unloading port 1340 is provided at the side of the housing 1310 adjacent to the vacuum transfer chamber 170. The substrate loading/unloading port 1340 is opened or closed by a gate valve 1350. When the substrate loading/unloading port 1340 is opened by the gate valve 1350, the substrate 10 can be loaded into the vacuum transfer chamber 170 or unloaded out of the vacuum transfer chamber 170.

A substrate mounting table 1320 on which the substrate 10 can be placed is provided in the load lock chamber 1300.

### Vacuum Transfer Chamber 170

The substrate processing system 1 includes the vacuum transfer chamber (transfer module) 170, that is, a transfer space (transfer chamber) in which the substrate 10 is transferred under a negative pressure. For example, the load lock chamber 1300 and the substrate processing apparatus 101 configured to process the substrates 10 are connected to respective sides of the vacuum transfer chamber 170. A transfer device 30 serving as a vacuum transfer robot capable of transferring the substrate 10 between the load lock chamber 1300 and the chamber 180 under the negative pressure is provided at approximately a center of the vacuum transfer chamber 170 with a flange 35 as a base.

For example, the transfer device 30 includes components such as a tweezer 31 configured to support the substrate 10, an extendable arm 32, a rotating shaft 33, a base 34, the flange 35 and an elevator (which is an elevating structure) 36. The vacuum transfer chamber 170 is configured to be maintained airtight by the elevator 36 and the flange 35. By operating the transfer device 30 by using the elevator 36, the substrate 10 can be transferred between the load lock chamber 1300 and the boat 200.

### Substrate Processing Apparatus 101

The substrate processing apparatus 101 includes: a reaction tube constituted by the first reaction tube 110 of a cylindrical shape extending in the vertical direction and a second reaction tube 120 provided at an inner side of the first reaction tube 110; and a reaction tube heater 100 serving as a first heating structure (heating element) installed on an outer periphery of the first reaction tube 110. For example, each of the first reaction tube 110 and the second reaction tube 120 constituting the reaction tube is made of a material such as quartz (SiO₂) and silicon carbide (SiC). An inner atmosphere of the first reaction tube 110 is hermetically sealed with respect to an outside air by a component such as a seal (not shown), and a process chamber 115 is defined by an inside of the second reaction tube 120. In the present specification, the first reaction tube 110 may also be referred to as an “outer cylinder”, an “outer tube” or an “outer reaction tube”. The second reaction tube 120 may also be referred to as an “inner cylinder”, an “inner tube” or an “inner reaction tube”. While the present embodiments will be described by way of an example in which the reaction tube is constituted by the first reaction tube 110 and the second reaction tube 120, the present embodiments are not limited thereto. For example, even when the reaction tube is constituted by the first reaction tube 110 alone, the technique of the present disclosure can be applied.

For example, the reaction tube heater 100 may be constituted by a zone heater including a plurality of zones divided in the vertical direction so as to be capable of performing a zone control in the vertical direction.

### Substrate Retainer

The boat 200 serving as the substrate retainer is supported by a support rod 160 via a heat insulator 150. For example, the boat 200 is constituted by: a plurality of support columns 202 standing vertically; a plurality of disks 201 supported by the support columns 202, respectively, at regular intervals; and a plurality of substrate support structures 203 supported by the support columns 202, respectively, between the disks 201. In the boat 200, the substrates (for example, five substrates) 10 are vertically arranged and supported in a multistage manner by placing the substrates 10 on the substrate support structures 203 attached to the support columns 202, respectively, in spaces partitioned by the disks 201. For example, the substrates 10 are supported in the boat 200 while the substrates 10 are horizontally oriented with their centers aligned with one another. For example, the substrates 10 are arranged at regular intervals in the boat 200. For example, the boat 200 is made of a heat resistant material such as quartz and silicon carbide. A substrate retaining structure is constituted by the heat insulator 150 and the boat 200.

When the substrates 10 are processed, the boat 200 is accommodated in the second reaction tube 120 as shown in FIG. 2. While the present embodiments will be described by way of an example in which the five substrates 10 are supported in the boat 200, the present embodiments are not limited thereto. For example, the boat 200 may be configured to support about 5 substrates to 50 substrates as the substrates 10. In addition, the disks 201 may also be referred to as “separators”.

### Heat Insulator 150

The heat insulator 150 is configured such that a conduction or transmission of a heat tends to be reduced in the vertical direction. In addition, a cavity may be provided in the heat insulator 150. For example, a hole may be provided on a lower surface of the heat insulator 150. By providing the hole, it is possible to prevent a pressure difference from occurring between an inside and an outside of the heat insulator 150, and it is also possible to prevent a wall of the heat insulator 150 from thickening. In addition, a cap heater 152 may be provided in the heat insulator 150.

### Chamber 180

The chamber 180 is provided at a lower portion of the second reaction tube 120, and includes the transfer chamber 300. For example, the transfer chamber 300 is constituted by a transfer space 330 and a heating space 340. The heat insulator 150 supported by the support rod 160 and the boat 200 is accommodated in the transfer chamber 300. A boat elevator 40 serving as an elevating structure of the boat 200 is provided outside the transfer chamber 300, for example, below the transfer chamber 300. The transfer space 330 is configured as a space in which the substrate 10 is placed (mounted) on the boat 200 and taken out from the boat 200. The heating space 340 is configured as a space in which the substrate 10 placed on the boat 200 is heated.

A vertical length of the transfer space 330 is set to be shorter than a vertical length of the heating space 340. In other words, the vertical length of the heating space 340 is set to be longer than the vertical length of the transfer space 330. By such a length relationship, it is possible to shorten a time from placing the substrate 10 on the boat 200 to heating the substrate 10, which will be described later.

A cooling flow path 190 may be provided at a substrate loading/unloading port 331. In such a case, the heat from the boat 200 (which is heated), the reaction tube heater 100 and a transfer chamber heater 321 described later may be transferred to the cooling flow path 190. As a result, a temperature elevation rate of a new substrate 10 (which refers to a substrate to be processed after the substrate 10 is processed) described later may be lowered. Hereinafter, a plurality of new substrates including the new substrate 10 may also be simply referred to as “new substrates 10”.

By such a length relationship described above, it is possible to dispose the new substrate 10 away from a low temperature region near the cooling flow path 190, and it is also possible to improve the temperature elevation rate of the new substrate 10. In addition, the vertical length of the heating space 340 may refer to an entire vertical length of a structure including the heat insulator 150 and a substrate placing region of the boat 200.

In the present embodiments, the chamber 180 is made of a metal material such as stainless steel (SUS) and aluminum (Al). In such a case, the transfer chamber 300 of the chamber 180 may be expanded by the heating space 340. In such a case, as shown in FIG. 1, a cooling flow path 191 may be provided outside the transfer chamber 300 of the chamber 180 such that the transfer chamber 300 can be cooled.

For example, an inert gas supply pipe 301 through which an inert gas is supplied is provided in the transfer chamber 300 of the chamber 180. By supplying the inert gas into the transfer chamber 300 through the inert gas supply pipe 301, it is possible to adjust an inner pressure of the transfer chamber 300 to be higher than an inner pressure of the first reaction tube 110. With such a configuration, it is possible to prevent (or suppress) a gas such as a process gas supplied to the process chamber 115 inside the first reaction tube 110 from entering the transfer chamber 300.

### Heating Apparatus 320

The heating space 340 refers to the space in which the substrate 10 is heated by a heating apparatus 320 constituted by components such as the transfer chamber heater 321, and is provided below the transfer space 330. When the substrate 10 is heated in the chamber 180, the boat 200 is in standby in the transfer space 330. In such a case, a space where the boat 200 is in standby may be referred to as a “boat standby area”. As shown in FIGS. 2 through 4, the heating apparatus 320 may include: the transfer chamber heater 321 serving as a second heating structure configured to heat the substrate 10; and a heat retaining plate 322 serving as a heat retaining structure disposed between the transfer chamber heater 321 and the boat 200 provided in the transfer chamber 300. That is, the heat retaining plate 322 is arranged between the transfer chamber heater 321 and the boat standby area. In other words, the transfer chamber heater 321 and the heat retaining plate 322 are provided around the boat 200. A cooling structure capable of cooling the transfer chamber heater 321 with a cooling water may be provided on an outside of the transfer chamber heater 321 (on a back surface thereof opposite to a surface facing the heat retaining plate 322), that is, on a wall constituting the chamber 180. With such a configuration, it is possible to prevent a temperature elevation within a vacuum chamber such as the vacuum transfer chamber 170.

For example, the transfer chamber heater 321 may be configured by a plurality of rod-shaped lamp heaters provided corresponding to a position of the boat 200 disposed within the transfer chamber 300. For example, each of the rod-shaped lamp heaters extends perpendicularly to the substrates 10, and is provided in the horizontal direction with respect to the substrates 10. The rod-shaped lamp heaters serving as a lamp heating apparatus are configured to heat the substrates 10 supported on the boat 200 from side surfaces of the substrates 10 through the heat retaining plate 322. For example, it is preferable to use a straight halogen lamp or an infrared lamp as each of the rod-shaped lamp heaters. Alternatively, the transfer chamber heater 321 may be configured by a plurality of rod-shaped lamp heaters extending horizontally to the substrates 10 and provided in the vertical direction with respect to the substrates 10.

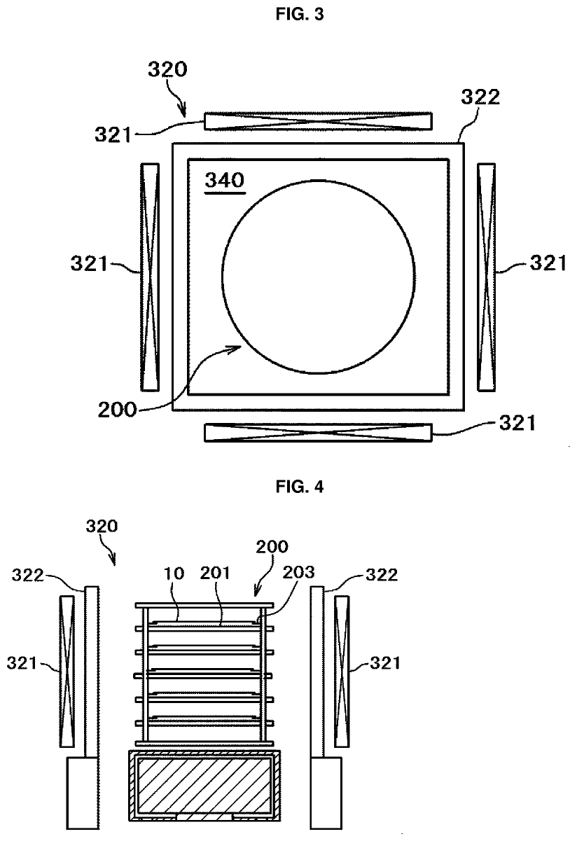

As shown in FIG. 3, the heat retaining plate 322 is configured as a polygonal cylinder of a polygon shape such as a quadrangle shape when viewed from above. The heat retaining plate 322 provided with a plurality of side surfaces is installed perpendicularly to the substrates 10 placed on the boat 200. Thereby, a space between the boat 200 and the transfer chamber heater 321 is surrounded by the heat retaining plate 322. It is preferable that the heat retaining plate 322 is made of a material whose absorption rate of the heat emitted from the transfer chamber heater 321 is high and whose thermal conductivity is high. By using the material whose thermal conductivity is high for the heat retaining plate 322, even when the heating surface of the transfer chamber heater 321 is small, it is possible to increase a heating area for the boat 200 by increasing a heating surface of the heat retaining plate 322. Further, it is preferable that the heat retaining plate 322 is made of a material whose thermal expansion rate is small and whose corrosion resistance is high). Thereby, it is possible to prevent a generation of particles within the vacuum chamber. For example, it is preferable that the heat retaining plate 322 is made of silicon carbide. Since components such as the lamp heaters may emit infrared rays whose wavelength is within a range from 1.0 μm to 1.1 μm, a non-uniform heating may occur depending on whether or not the light (infrared rays) is irradiated. However, by surrounding the boat 200 with the heat retaining plate 322, it is possible to uniformize the heat in the heating space 340. Thereby, it is possible to suppress the non-uniform heating.

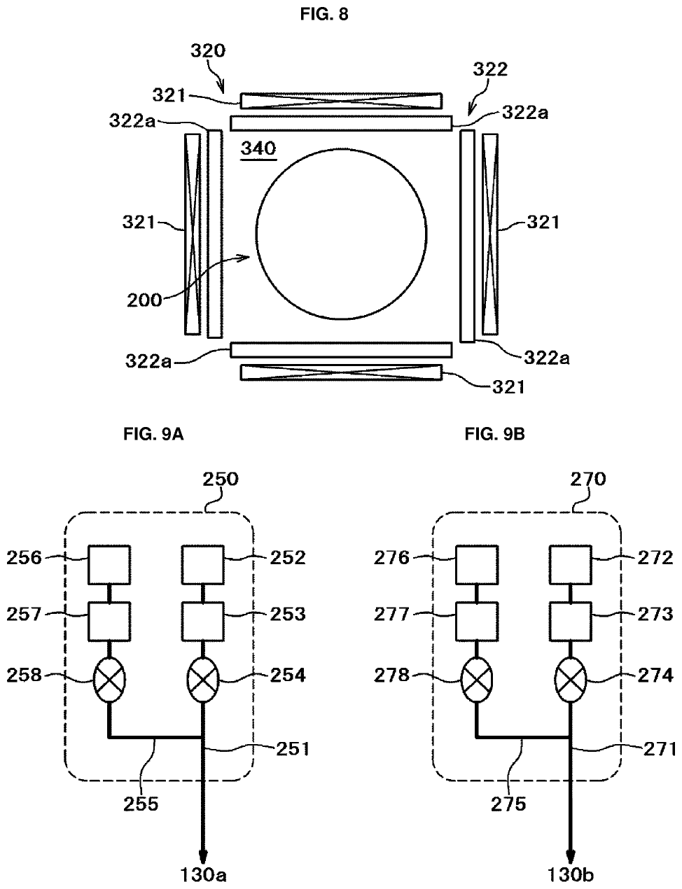

As shown in FIG. 8, the heat retaining plate 322 may be constituted by a plurality of separated plates 322a. That is, the plates 322a are provided so as to cover the boat 200. In such a case, a restraining plate made of a material such as SUS may be used to support the plates 322a from both sides thereof.

### Transfer space 330

In the transfer space 330, the substrate 10 placed on the boat 200 is transferred (taken out) from the boat 200 via the substrate loading/unloading port 331 using the transfer device 30, and the new substrate 10 is placed on the boat 200. In addition, at the substrate loading/unloading port 331, a gate valve (GV) 332 configured to separate the transfer space 330 from the chamber 180 is provided.

The support rod 160 is supported by the boat elevator 40. The boat elevator 40 is driven to move the support rod 160 up and down to load the boat 200 into the second reaction tube 120 and to unload the boat 200 out of the second reaction tube 120. The support rod 160 is connected to a rotation driver 42 provided at the boat elevator 40. By rotating the support rod 160 by the rotation driver 42, it is possible to rotate the heat insulator 150 and the boat 200.

The substrate processing system 1 is configured to supply the gas such as the process gas used for the substrate processing from a gas supplier (which is a gas supply system) described later through a nozzle 130 provided in the second reaction tube 120.

The gas supplied through the nozzle 130 may be appropriately changed in accordance with a type of a film to be formed. Gases such as a source gas, a reactive gas and the inert gas are supplied into the second reaction tube 120 through the nozzle 130. For example, the nozzle 130 includes two nozzles 130a and 130b and is configured such that different types of gases can be supplied through the nozzles 130a and 130b, respectively. The nozzle 130 may also be referred to as a “gas supply structure”.

The nozzle 130 is connected to the gas supplier shown in FIGS. 9A and 9B. In FIGS. 9A and 9B, a reference numeral 250 indicates a first gas supplier (which is a first gas supply system), and a reference numeral 270 indicates a second gas supplier (which is a second gas supply system). The first gas supplier 250 may include a gas supply pipe 251 capable of communicating with the nozzle 130a. The second gas supplier 270 may include a gas supply pipe 271 capable of communicating with the nozzle 130b.

In the first gas supplier 250, as shown in FIG. 9A, a first gas supply source 252, a mass flow controller (MFC) serving as a flow rate controller (flow rate control structure) 253 and a valve 254 serving as an opening/closing valve are sequentially installed at the gas supply pipe 251 in this order from an upstream side to a downstream side of the gas supply pipe 251 in a gas flow direction.

The first gas supply source 252 is a source of a first gas (also referred to as a “first element-containing gas”) containing a first element. The first element-containing gas serves as the source gas, which is one of process gases. According to the present embodiments, for example, the first element is silicon (Si). More specifically, a chlorosilane source gas containing a silicon—chlorine bond (Si—Cl bond) such as hexachlorodisilane (Si₂Cl₆, abbreviated as HCDS) gas, monochlorosilane (SiH₃Cl, abbreviated as MCS) gas, dichlorosilane (SiH₂Cl₂, abbreviated as DCS) gas, trichlorosilane (SiHCl₃, abbreviated as TCS) gas, tetrachlorosilane (SiCl, abbreviated as STC) gas and octachlorotrisilane (Si₃Cl₈, abbreviated as OCTS) gas may be used as the first element-containing gas.

The first gas supplier 250 is constituted mainly by the gas supply pipe 251, the MFC 253 and the valve 254. The first gas supplier 250 may also be referred to as a “silicon-containing gas supplier” (which is a silicon-containing gas supply system).

A gas supply pipe 255 is connected to the gas supply pipe 251 at a downstream side of the valve 254. An inert gas supply source 256, a mass flow controller (MFC) 257 and a valve 258 serving as an opening/closing valve are sequentially installed at the gas supply pipe 255 in this order from an upstream side toward a downstream side of the gas supply pipe 255 in the gas flow direction. For example, the inert gas such as nitrogen (N₂) gas is supplied from the inert gas supply source 256.

A first inert gas supplier (which is a first inert gas supply system) is constituted mainly by the gas supply pipe 255, the MFC 257 and the valve 258. The inert gas supplied from the inert gas supply source 256 is used as a purge gas for purging the gas remaining in the reaction tube during the substrate processing described later. The first gas supplier 250 may further include the first inert gas supplier.

In the second gas supplier 270, as shown in FIG. 9B, a second gas supply source 272, a mass flow controller (MFC) serving as a flow rate controller (flow rate control structure) 273 and a valve 274 serving as an opening/closing valve are sequentially installed at the gas supply pipe 271 in this order from an upstream side to a downstream side of the gas supply pipe 271 in the gas flow direction.

The second gas supply source 272 is a source of a second gas (also referred to as a “second element-containing gas”) containing a second element. The second element-containing gas serves as one of the process gases. Further, the second element-containing gas may serve as the reactive gas or a modification gas.

According to the present embodiments, for example, the second element-containing gas contains the second element different from the first element. As the second element, for example, one of oxygen (O), nitrogen (N) and carbon (C) may be used. According to the present embodiments, for example, a nitrogen-containing gas is used as the second element-containing gas. More specifically, a hydrogen nitride-based gas containing a nitrogen—hydrogen bond (N—H bond) such as ammonia (NH₃), diazene (N₂H₂) gas, hydrazine (N₂H₄) gas and N₃H₈ gas may be used as the second element-containing gas.

The second gas supplier 270 is constituted mainly by the gas supply pipe 271, the MFC 273 and the valve 274.

A gas supply pipe 275 is connected to the gas supply pipe 271 at a downstream side of the valve 274. An inert gas supply source 276, a mass flow controller (MFC) 277 and a valve 278 serving as an opening/closing valve are sequentially installed at the gas supply pipe 275 in this order from an upstream side toward a downstream side of the gas supply pipe 275 in the gas flow direction. For example, the inert gas such as nitrogen (N₂) gas is supplied from the inert gas supply source 276.

A second inert gas supplier (which is a second inert gas supply system) is constituted mainly by the gas supply pipe 275, the MFC 277 and the valve 278. The inert gas supplied from the inert gas supply source 276 is used as the purge gas for purging the gas remaining in the reaction tube during the substrate processing described later. The second gas supplier 270 may further include the second inert gas supplier.

In the present embodiments, the first gas supplier 250 and the second gas supplier 270 may be collectively referred to as the “gas supplier”. While the present embodiments will be described by way of an example in which the two gas suppliers (that is, the first gas supplier 250 and the second gas supplier 270) are used, the present embodiments are not limited thereto. For example, one gas supplier or three or more gas suppliers may be used depending on contents of the substrate processing.

For example, among the gases supplied through the nozzle 130 into the second reaction tube 120, the reactive gas which did not contribute to a formation of the film passes through a gap 121 (which is provided between the second reaction tube 120 and an upper portion of the first reaction tube 110) and an opening 122 (which is provided between the second reaction tube 120 and a lower portion of the first reaction tube 110). Then, the reactive gas is exhausted to an outside of the substrate processing system 1 by an exhaust pump (not shown) through an exhaust pipe 140 serving as an exhauster (which is an exhaust structure).

### Controller 260

As shown in FIGS. 1 and 5, the substrate processing apparatus 101 or the substrate processing system 1 includes a controller 260 configured to control operations of components constituting the substrate processing apparatus 101 or the substrate processing system 1.

As shown in FIG. 5, the controller 260 serving as a control structure (control apparatus) is constituted by a computer including a CPU (Central Processing Unit) 260a, a RAM (Random Access Memory) 260b, a memory 260c and an I/O port 260d. The RAM 260b, the memory 260c and the I/O port 260d may exchange data with the CPU 260a through an internal bus 260e. For example, an input/output device 261 constituted by a component such as a touch panel and an external memory 262 may be connected to the controller 260.

For example, the memory 260c is constituted by components such as a flash memory and a hard disk drive (HDD). For example, a control program configured to control the operation of the substrate processing apparatus 101 and a process recipe containing information on sequences and conditions of the substrate processing described later may be readably stored in the memory 260c. The process recipe is obtained by combining steps of the substrate processing described later such that the controller 260 can execute the steps to acquire a predetermined result, and functions as a program. Hereafter, the process recipe and the control program may be collectively or individually referred to as a “program”. Thus, in the present specification, the term “program” mayrefer to the process recipe alone, may refer to the control program alone, or may refer to both of the process recipe and the control program. The RAM 260b functions as a memory area (work area) where a program or data read by the CPU 260a is temporarily stored.

The I/O port 260d is electrically connected to components such as the gate valves 1330, 1350 and 332, the elevator 36, the boat elevator 40, the reaction tube heater 100, the transfer chamber heater 321, a pressure regulator (not shown) and a vacuum pump (not shown). For example, the I/O port 260d may be electrically connected to components such as the transfer device 30 serving as the vacuum transfer robot, the atmospheric transfer robot 1220, the load lock chamber 1300 and the gas supplier (which constituted by the MFCs and the valves described above). For example, in the present specification, “electrically connected” means that the components are connected by physical cables or the components are capable of communicating with one another to transmit and receive signals (electronic data) to and from one another directly or indirectly. For example, a device for relaying the signals or a device for converting or computing the signals may be provided between the components.

The CPU 260a is configured to read and execute the control program from the memory 260c and read the process recipe from the memory 260c in accordance with an instruction such as an operation command inputted from the controller 260. The CPU 260a is configured to control various operations in accordance with the read process recipe such as opening and closing operations of the gate valves 1330, 1350 and 332, an elevating and lowering operation of the elevator 36, an elevating and lowering operation of the boat elevator 40, a rotating operation of the rotation driver 42, an operation of supplying electrical power to the reaction tube heater 100, an operation of supplying the electrical power to the transfer chamber heater 321, an operation of the transfer device 30 serving as the vacuum transfer robot and an operation of the atmospheric transfer robot 1220. For example, the CPU 260a is further configured to control an operation of the gas supplier (that is, operations of the MFCs and the valves described above), but illustration thereof is omitted.

The controller 260 is not limited to a dedicated computer, and may be embodied by a general-purpose computer. For example, the controller 260 according to the present embodiments may be embodied by preparing the external memory 262 (e.g., a magnetic tape, a magnetic disk such as a flexible disk and a hard disk, an optical disk such as a CD and a DVD, a magneto-optical disk such as an MO, a semiconductor memory such as a USB memory and a solid state drive (SSD)) in which the above-described program is stored, and by installing the program onto the general-purpose computer using the external memory 262. A method of providing the program to the computer (general-purpose computer) is not limited to the external memory 262. For example, the program may be directly provided to the computer by a communication instrument such as a network 263 (Internet and a dedicated line) instead of the external memory 262. The memory 260c and the external memory 262 may be embodied by a non-transitory computer-readable recording medium. Hereinafter, the memory 260c and the external memory 262 are collectively or individually referred to as a recording medium. In the present specification, the term “recording medium” mayrefer to the memory 260c alone, may refer to the external memory 262 alone, or may refer to both of the memory 260c and the external memory 262.

### (2) Substrate Processing

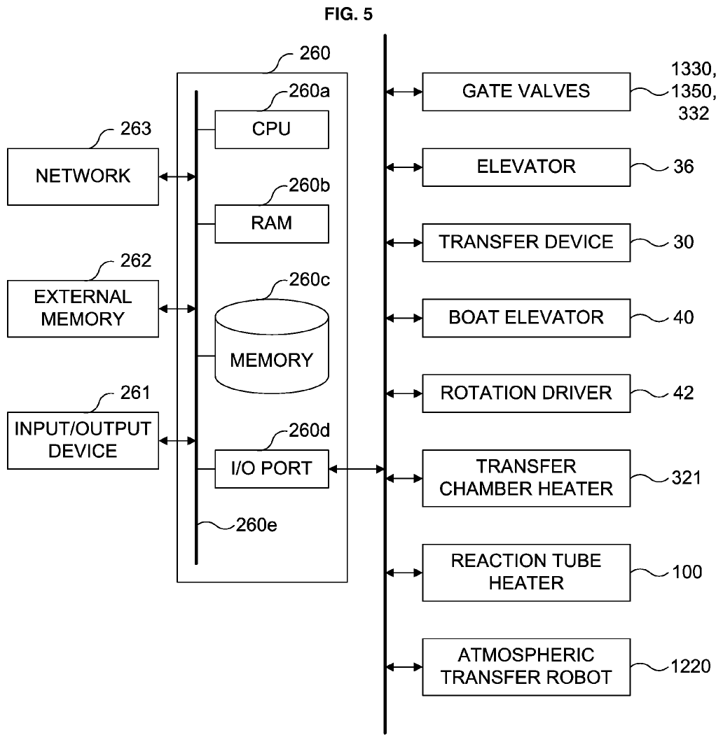

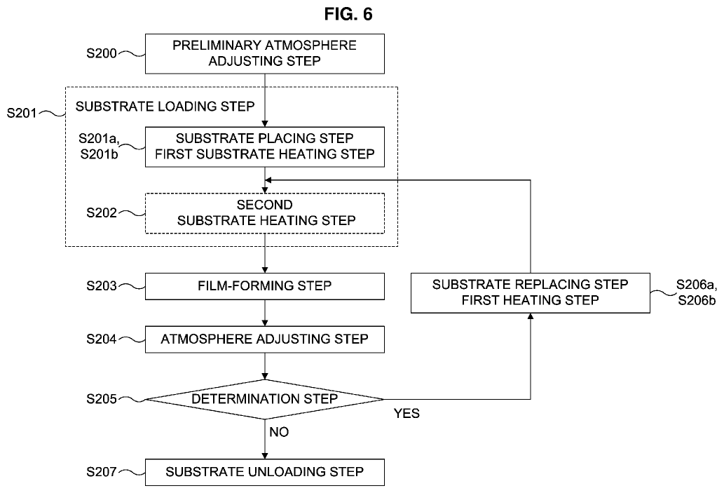

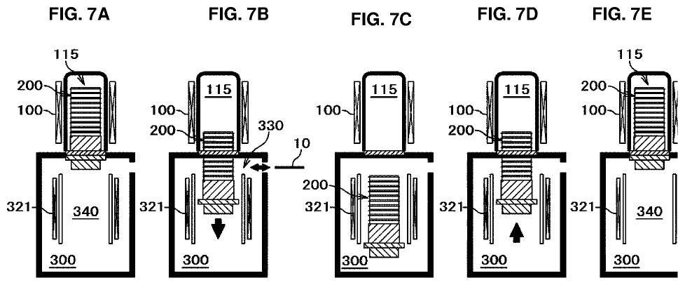

Hereinafter, the substrate processing (film-forming process) of forming a film on the substrate 10, which is a part of a manufacturing process of a semiconductor device, by using the substrate processing apparatus 101 described above will be described with reference to FIGS. 6 and FIGS. 7A through 7E. For example, as the film, a silicon oxide film (SiO film) serving as an insulating film and a silicon-containing film is formed on the substrate 10. In FIGS. 7A through 7E, examples in which ten substrates serving as the substrates 10 are supported on the boat 200 are shown. In the following description, operations of the components constituting the substrate processing apparatus 101 are controlled by the controller 260.

In the present specification, the terms “substrate” and “wafer” maybe used as substantially the same meaning. In such case, in the above descriptions, the term “substrate” maybe replaced with the term “wafer”.

Hereinafter, an exemplary process flow of a series of the substrate processing including a film-forming step S203 of forming the film on the substrate 10, which is a part of the manufacturing process of the semiconductor device, will be described.

### Preliminary Atmosphere Adjusting Step S200

First, the process chamber 115 and the boat 200 are heated by the reaction tube heater 100 to a predetermined temperature of the film-forming step S203. In the present step, the process chamber 115 and the boat 200 are heated in a state in which the boat 200 is arranged at a process position shown in FIG. 7A. After the process chamber 115 and the boat 200 are heated to the predetermined temperature, an inner atmosphere of the process chamber 115 is vacuum-exhausted through the exhaust pipe 140 (see FIG. 1) by the vacuum pump (not shown) such that an inner pressure of the process chamber 115 reaches and is maintained at a desired pressure (vacuum vacuum). Further, the reaction tube heater 100 continuously heats the process chamber 115 and the vacuum pump continuously vacuum-exhausts the inner atmosphere of the process chamber 115 until at least a processing of the substrate 10 is completed.

In addition, the transfer chamber heater 321 may be turned on such that an inside of the heating space 340 is preliminary heated to a predetermined temperature.

### Substrate Loading Step S201

Subsequently, a substrate loading step S201 is performed. In the substrate loading step S201, at least a substrate placing step S201a and a first substrate heating step S201b are performed.

### Substrate Placing Step S201a and First Substrate Heating Step S201b

In the substrate loading step S201, the substrate placing step S201a and the first substrate heating step S201b are performed in parallel. In the substrate placing step S201a and the first substrate heating step S201b, the transfer chamber heater 321 is turned on such that the inside of the heating space 340 is preliminary heated to the predetermined temperature.

### Substrate Placing Step S201a

First, the substrate placing step S201a will be described. A step of mounting (placing) the substrates 10 on the boat 200 is performed. Specifically, from a state shown in FIG. 7A, a lowermost substrate support structure among the substrate support structures 203 of the boat 200 is inserted into the transfer space 330 of the transfer chamber 300 as in a state shown in FIG. 7B. Such a state may also be referred to as a state in which one pitch (a substrate support structure on which a substrate is placed) is inserted into the transfer space 330. In such a state, most of the boat 200 faces the reaction tube heater 100 and is in a heated state. In such a state, the substrate 10 is placed on a substrate support structure (that is, a lowermost substrate support structure among the substrate support structures 203) of the boat 200 from the transfer device 30 through the substrate loading/unloading port 331 of the transfer space 330 (see FIG. 1). Such an operation is repeatedly performed while lowering the substrate support structures 203 of the boat 200 by one pitch (boat down) by moving the support rod 160 (see FIG. 1) by the boat elevator 40 (see FIG. 1) such that the substrates 10 are placed on the substrate support structures 203 at an entirety of stages of the boat 200.

### First Substrate Heating Step S201b

Subsequently, the first substrate heating step S201b will be described with reference to FIG. 7B. The first substrate heating step S201b is performed in order from the substrate 10 placed on the boat 200 in the substrate placing step S201a described above. The substrate 10 placed on the boat 200 is heated by the transfer chamber heater 321. A step of heating the substrate 10 in a manner described above is referred to as the “first substrate heating step S201b”. As in a state shown in FIG. 7C, the first substrate heating step S201b is continuously performed until the substrates 10 are placed on the substrate support structures 203 at the entirety of stages of the boat 200. In the present step, for example, the substrate 10 is heated to a temperature within a range from about 200° C. to about 450° C.

For example, in the substrate placing step S201a, a rotation of the boat 200 is stopped. Since the rotation of the boat 200 is stopped, a temperature difference (temperature distribution) may be generated along a rotation direction (circumferential direction) of the substrate 10 or the boat 200 depending on the rotation direction of the boat 200 (circumferential direction of the substrate 10). For example, a temperature of a portion facing the substrate loading/unloading port 331 may be lower than temperatures of other portions. In order to eliminate the temperature difference, it is preferable to rotate the boat 200 after a substrate among the substrates 10 is placed on an uppermost substrate support structure among the substrate support structures 203 of the boat 200.

### Second Substrate Heating Step S202

For example, before the boat 200 is elevated, a second substrate heating step S202 may be performed. In the second substrate heating step S202, the boat 200 is in standby in the boat standby area for a predetermined time in the state shown in FIG. 7C. Further, while rotating the boat 200 to eliminate the temperature difference in the circumferential direction of the substrate 10, the transfer chamber heater 321 heats the substrate 10 in the heating space 340 to a predetermined temperature. For example, the substrate 10 is heated to a temperature within a range from about 200° C. to about 450° C.

Subsequently, in a state in which the substrates 10 are placed on the substrate support structures 203 at the entirety of stages of the boat 200, as shown in FIG. 7D, the boat elevator 40 elevates the support rod 160 to transfer (load) the boat 200 into the second reaction tube 120 (boat loading). In a state shown in FIG. 7D, the transfer chamber heater 321 is turned on (in operation).

When the boat loading is performed, a temperature at a lower portion of the process chamber 115 may overshoot. In such a case, it is preferable that the reaction tube heater 100 is constituted by the zone heater including the plurality of zones divided in the vertical direction and an output of a zone heater provided at a lower zone is set to be small than those of other heaters provided at other zones.

In such a state, since inner atmospheres of the transfer chamber 300 and the process chamber 115 are vacuum-exhausted through the exhaust pipe 140 by the vacuum pump (not shown), the boat 200 is loaded into the process chamber 115 from the transfer chamber 300 in a vacuum state. Thereby, it is possible to eliminate a process to vacuum-exhaust the process chamber 115 after loading the boat 200 from the transfer chamber 300 to the process chamber 115. As a result, it is possible to shorten an overall process time. By loading the boat 200 from the transfer chamber 300 to the process chamber 115 in the vacuum state in a manner described above, it is possible to suppress a temperature decrease in the process chamber 115. In addition, it is possible to suppress a temperature decrease in the substrate 10 while the substrate 10 after heated is moved from the heating space 340 of the transfer chamber 300 to the process chamber 115.

As shown in FIG. 7E, after the boat 200 is loaded, the reaction tube heater 100 heats an inside of the process chamber 115 to a desired temperature. In such a case, since the boat 200 and the substrates 10 are already heated in the transfer chamber 300, it is possible to significantly shorten a time for elevating the temperatures of the boat 200 and the substrates 10 to a temperature appropriate for starting the film-forming process as compared with a case where the boat 200 (and the substrates 10) are loaded into the process chamber 115 at the room temperature without being heated in the transfer chamber 300. Thereby, it is possible to shorten a process time of the substrate processing, and it is also possible to improve a throughput. For example, in a state shown in FIG. 7E, the transfer chamber heater 321 is turned off (not in operation).

### Film-Forming Step S203

Subsequently, the source gas is supplied from the gas supplier into the second reaction tube 120 through the nozzle 130, and is exhausted to the outside of the substrate processing system 1 by the exhaust pump (not shown) through the exhaust pipe 140 via the gap 121 (which is provided between the second reaction tube 120 and the upper portion of the first reaction tube 110) and the opening 122 (which is provided between the second reaction tube 120 and the lower portion of the first reaction tube 110).

By repeatedly performing a processing including a step of supplying the source gas into the second reaction tube 120 through the nozzle 130 and exhausting the source gas to the outside by the exhaust pump, it is possible to form the film of a desired thickness on the surface of the substrate 10 mounted (placed) on the boat 200.

Subsequently, an alternate supply process (which is an example of the processing described above) will be described. In the alternate supply process, different gases are alternately supplied to form a desired film on the substrate 10.

For example, in a first step of the alternate supply process, the first gas is supplied from the first gas supplier 250 to the process chamber 115, and in a subsequent second step of the alternate supply process, the second gas is supplied from the second gas supplier 270 to the process chamber 115 to form a desired film. Between the first step and the second step, a purge step is provided to exhaust the inner atmosphere of the process chamber 115. For example, by performing a combination of the first step, the purge step and the second step at least once, preferably a plurality of times, it is possible to form a silicon-containing film serving as the film on the substrate 10.

### Atmosphere Adjusting Step S204

After the film of the desired thickness is formed on the surface of the substrate 10, an atmosphere adjusting step S204 is performed. Nitrogen (N₂) gas is supplied from the gas supplier into the second reaction tube 120 through the nozzle 130, and is exhausted to the outside of the substrate processing system 1 by the exhaust pump (not shown) through the exhaust pipe 140 such that that the inside of the process chamber 115 is purged with the inert gas to remove a substance (such as the gas and by-products remaining in the process chamber 115) from the process chamber 115.

### Determination Step S205

Subsequently, a determination step S205 of determining whether to repeatedly perform the film-forming step S203 described above on the new substrates 10 (which are unprocessed) is performed. When there are the new substrates 10 (“YES” in FIG. 6), a substrate replacing step S 206a and a first heating step S206b are performed. When there are no new substrates 10 (“NO” in FIG. 6), a substrate unloading step S 207 is performed.

### Substrate Replacing Step S206a and First Heating Step S206b

When there are the new substrates 10, the substrate replacing step S206a and the first heating step S206b are performed in parallel.

### Substrate Replacing Step S206a

After it is determined that there are the new substrates 10, by lowering the support rod 160 from the state shown in FIG. 7A by operating the boat elevator 40, the boat 200 accommodating the substrates 10 with the film of the predetermined thickness formed on the surfaces thereof is transferred to the transfer chamber 300 as shown in FIG. 7B.

When the boat 200 accommodating the substrates 10 with the film of the predetermined thickness formed on the surfaces thereof is transferred to the chamber 180, according to the present embodiments, a step of taking out a substrate among the substrates 10 with the film formed on the surface thereof from the boat 200 through the substrate loading/unloading port 331 of the transfer space 330 and a step of mounting (or placing) a new substrate among the new substrates 10 on the boat 200 are performed one by one by driving the boat elevator 40 to transfer the boat 200 by one pitch until the substrates 10 are completely taken out and the new substrates 10 are completely mounted (placed).

There are various orders for replacing the substrates 10 such as from the top, from the bottom and from near a middle of the boat 200. For example, when the substrates 10 are replaced from the bottom of the boat 200, it is possible to shorten a temperature elevation time of the substrates 10. However, since temperatures of an uppermost substrate and a lowermost substrate (among the substrates 10) mounted on the boat 200 tend to be higher than a temperature of a substrate (among the substrates 10) mounted near the middle of the boat 200, the substrates 10 maybe replaced from near the middle of the boat 200.

As shown in FIG. 7C, an operation of replacing the substrate 10 with the new substrate 10 is repeatedly performed until the substrates 10 with the film formed thereon mounted on the boat 200 are completely replaced with the new substrates 10.

### First Heating Step S206b

In the first heating step S206b, the substrates 10 are heated similarly to the first substrate heating step S201b described above. Thereafter, the second substrate heating step S202 and subsequent steps are performed.

The embodiments described above are described by way of an example in which the substrates 10 with the film formed thereon are taken out from the boat 200 and the new substrates 10 are mounted (placed) onto the boat 200 one by one by driving the boat elevator 40 to transfer the boat 200 by one pitch until the substrates 10 are completely replaced with the new substrates 10. However, two or more substrates among the substrates 10 maybe simultaneously taken out from the boat 200 and two or more new substrates among the new substrates 10 maybe simultaneously mounted onto the boat 200. In such a case, the boat elevator 40 transfers the boat 200 by pitches corresponding to the two or more substrates among the substrates 10.

In addition, after the two or more substrates among the substrates 10 are simultaneously taken out from the boat 200 and the two or more new substrates among the new substrates 10 are simultaneously mounted (placed) onto the boat 200, the two or more new substrates among the new substrates 10 (which are unprocessed) newly mounted on the boat 200 may be collectively heated.

In addition, when the boat 200 is lowered by the boat elevator 40 and the substrates 10 (which are mounted on the boat 200) with the film formed thereon are replaced with the new substrates 10, the reaction tube heater 100 of the substrate processing apparatus 101 may continuously heat the process chamber 115. As a result, it is possible to suppress a temperature decrease in an upper portion of the boat 200. Accordingly, since a heating time of the heating space 340 corresponding to a new substrate (among the new substrates 10) provided at the upper portion of the boat 200 is short after the substrates 10 are replaced with the new substrates 10, it is possible to reduce a temperature difference between the new substrate (among the new substrates 10) provided at the upper portion of the boat 200 and a new substrate (among the new substrates 10) provided at a lower portion of the boat 200 to some extents.

Further, in the substrate replacing step S206a, the cap heater 152 may be continuously turned on to perform the boat down and the boat loading. By continuously turning on the cap heater 152, it is possible to suppress a temperature decrease in the heat insulator 150 and a temperature decrease of the substrate support structures 203 at the lower portion of the boat 200.

### Substrate Unloading Step S207

The substrate unloading step S207 is performed when there are no new substrates 10. An operation of the substrate unloading step S207 is configured such that no new substrate 10 is placed in the substrate replacing step S206a.

Thereby, the substrate processing according to the present embodiments is performed.

According to the present embodiments, it is possible to obtain one or more effects described below.

(1) The transfer chamber communicating with the lower portion of the process chamber is configured to accommodate a substrate retainer configured to support the plurality of substrates, a heater configured to heat a plurality of substrates and at least one heat retaining structure provided between the substrate retainer and the heater (heating structure) such as the transfer chamber heater 321. As a result, the heat retaining structure heated by the heater can prevent the temperature decrease of the substrate retainer during a transfer process. It is possible to shorten a temperature elevation time in the process chamber, and it is also possible to improve a productivity of the substrate processing apparatus.

(2) The heater is provided around the substrate retainer. As a result, it is possible to increase a thermal efficiency since a distance between a heat source and the substrate is short.

(3) The heat retaining structure is provided around the substrate retainer. As a result, it is possible to increase a heat retention since a distance between the heat retaining structure and the substrate is short.

(4) A plurality of heat retaining structures are provided so as to cover the substrate retainer. As a result, it is possible to suppress the non-uniform heating.

(5) The heater is configured as a lamp heating apparatus. As a result, it is possible to shorten the temperature elevation time. In addition, the lamp heating apparatus includes a heating element sealed inside a quartz tube. Thereby, it is possible to reduce a risk of contamination within the vacuum chamber.

(6) The heat retaining structure is made of silicon carbide with uniform heat properties. As a result, it is possible to improve the heat retention. In addition, since no heat insulating material made of a glass fiber is used, it is possible to obtain a clean heat retaining structure inside the vacuum chamber.

### Other Embodiments of Present Disclosure

While the technique of the present disclosure is described in detail by way of the embodiments described above, the technique of the present disclosure is not limited thereto. The technique of the present disclosure may be modified in various ways without departing from the scope thereof. For example, the embodiments described above are described in detail to clearly explain the technique of the present disclosure, and the technique of the present disclosure is not limited to those including an entirety of the configurations described herein. In addition, it is possible to add or delete a configuration of each embodiment, or replace a configuration of each embodiment with another configuration.

According to some embodiments of the present disclosure, it is possible to improve a heating efficiency for the substrate.

What is claimed is:

1. A substrate processing apparatus comprising:
a process chamber in which a plurality of substrates are processed; and
a transfer chamber communicating with a lower portion of the process chamber and configured to be capable of accommodating:
a substrate retainer configured to support the plurality of substrates;
a heating structure configured to heat the plurality of substrates; and
at least one heat retaining structure provided between the substrate retainer and the heating structure.

2. The substrate processing apparatus of claim 1, wherein the at least one heat retaining structure is provided around the substrate retainer.

3. The substrate processing apparatus of claim 1, wherein a plurality of heat retaining structure are provided as the at least one heat retaining structure so as to cover the substrate retainer.

4. The substrate processing apparatus of claim 1, wherein the at least one heat retaining structure is provided perpendicular to the plurality of substrates.

5. The substrate processing apparatus of claim 1, wherein the at least one heat retaining structure is constituted by a plurality of plates.

6. The substrate processing apparatus of claim 1, wherein the at least one heat retaining structure is configured as a polygonal cylinder of a polygon shape when viewed from above.

7. The substrate processing apparatus of claim 1, wherein the at least one heat retaining structure is made of a material whose absorption rate of a heat emitted from the heating structure is high and whose thermal conductivity is high.

8. The substrate processing apparatus of claim 1, wherein the at least one heat retaining structure is made of a material whose thermal expansion rate is small and whose corrosion resistance is high.

9. The substrate processing apparatus of claim 1, wherein the at least one heat retaining structure is made of silicon carbide.

10. The substrate processing apparatus of claim 1, wherein the heating structure is provided around the substrate retainer.

11. The substrate processing apparatus of claim 1, wherein the heating structure comprises a plurality of heaters arranged in a horizontal direction with respect to the plurality of substrates.

12. The substrate processing apparatus of claim 11, wherein each of the plurality of heaters is of a rod shape arranged in the horizontal direction.

13. The substrate processing apparatus of claim 1, wherein the heating structure comprises a lamp heating apparatus.

14. The substrate processing apparatus of claim 1, wherein each of the plurality of substrates is heated to a predetermined temperature by the heating structure in the transfer chamber.

15. The substrate processing apparatus of claim 1, wherein, in the transfer chamber, a substrate among the plurality of substrates supported by the substrate retainer is taken out from the substrate retainer and another substrate is placed onto the substrate retainer.

16. A method of manufacturing a semiconductor device, comprising:
(a) placing a plurality of substrates on a substrate retainer of a substrate processing apparatus comprising:
a process chamber in which the plurality of substrates are processed; and
a transfer chamber communicating with a lower portion of the process chamber and configured to be capable of accommodating:
the substrate retainer configured to support the plurality of substrates;
a heating structure configured to heat the plurality of substrates; and
at least one heat retaining structure provided between the substrate retainer and the heating structure; and
(b) processing the plurality of substrates in the process chamber.

17. The method of claim 16, further comprising
(c) heating the plurality of substrates to a predetermined temperature in the transfer chamber.

18. The method of claim 16, further comprising
(d) transferring the plurality of substrates into the process chamber.

19. A substrate processing method comprising:
(a) placing a plurality of substrates on a substrate retainer of a substrate processing apparatus comprising:
a process chamber in which the plurality of substrates are processed; and
a transfer chamber communicating with a lower portion of the process chamber and configured to be capable of accommodating:
the substrate retainer configured to support the plurality of substrates;
a heating structure configured to heat the plurality of substrates; and
at least one heat retaining structure provided between the substrate retainer and the heating structure; and
(b) processing the plurality of substrates in the process chamber.

20. A non-transitory computer-readable recording medium storing a program that causes a substrate processing apparatus, by a computer, to perform a process comprising the substrate processing method of claim 19.
